(19) United States
(12) Patent Application Publication
(10) Pub. No.: US 2015/0235981 A1
(43) Pub. Date: Aug. 20, 2015

(54) WIRE BONDING METHOD WITH TWO STEP FREE AIR BALL FORMATION

(71) Applicants: Poh Leng Eu, Petaling Jaya (MY); Cheng Choi Yong, Puchong (MY)

(72) Inventors: Poh Leng Eu, Petaling Jaya (MY); Cheng Choi Yong, Puchong (MY)

(21) Appl. No.: 14/552,441

(22) Filed: Nov. 24, 2014

(30) Foreign Application Priority Data
Feb. 14, 2014 (MY) PI2014700332

(51) Int. Cl. H01L 23/00

(52) U.S. Cl. CPC H01L 24/43; H01L 24/78; H01L 24/85; H01L 24/48; H01L 2924/01029; H01L 2224/85205; H01L 2224/431; H01L 2924/3651

(57) ABSTRACT

A method of attaching a bond wire to an electrical contact pad includes performing a first electric flame off (EFO) on the end of the bond wire at a first setting to pre-form a free air ball (FAB) on the end of the wire, and performing a second EFO on the end of the bond wire at a second setting, after performing the first EFO, to fully form the FAB.

### BACKGROUND OF THE INVENTION

The present invention relates to semiconductor device assembly and, more particularly, to a method of attaching a bond wire to a bond pad of a semiconductor die.

Many semiconductor devices use bond wires for connecting bond pads of an integrated circuit die to leads of a lead frame or pads of a substrate. Bond wires are formed from a conductive metal such as Gold or Aluminum. More recently there has been a push to use Copper wires due to Copper having good electrical characteristics and lower cost. However, Copper is harder and stiffer than Gold or Aluminum and therefore presents a new set of challenges for wire bonding, including good straightness for long wire lengths and well formed bonding balls. For example, FIG. 1A shows a side view of a wire 10 and a deformed or off-center free air ball (FAB) 12, while FIG. 1B shows a side view of the wire 10 and a uniformly shaped FAB 14. The off-center FAB 12 is less reliable than the uniform FAB 14 because the intermetallic compound (IMC) formation is not uniform across the ball bond when the ball is attached to a bond pad surface because the FAB 12 is not evenly pressed against the bond pad surface during the scrubbing action performed during the bonding process.

In view of the foregoing, it would be advantageous to be able to perform Copper wire bonding in a manner that addresses some of the difficulties presented by Copper wire.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1A is an enlarged side view of an off-center free air ball;

FIG. 1B is an enlarged side view of a well formed free air ball;

FIGS. 2-4 illustrate steps of forming a free air ball during a wire bonding process in accordance with an embodiment of the present invention; and

FIG. 5 is a schematic block diagram of a wire bonding apparatus in accordance with an embodiment of the present invention; and

FIG. 6 is an enlarged, partial side cross-sectional view of a semiconductor device assembled in accordance with an embodiment of the present invention.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

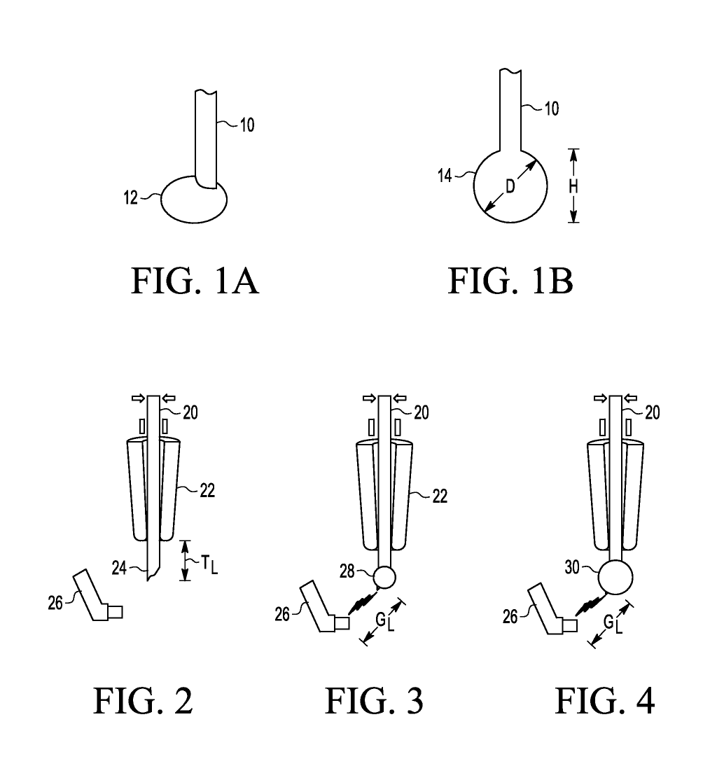

The present invention provides a method of forming free air balls, and more particularly, a method for preventing the formation of off-center free air balls. The present invention is particularly useful for forming free air balls from Copper wire, such as the FAB 14 (FIG. 1B), having a diameter D of 28 um and a height H that is equal to the diameter D. In one embodiment the present invention provides a method of attaching a bond wire to an electrical contact pad. The method includes holding the bond wire in a capillary, where an end of the wire extends out of an opening in the capillary; moving the bond wire towards the electrical contact pad; performing a first electric flame off (EFO) on the end of the bond wire at a first setting to pre-form a free air ball (FAB) on the end of the wire; and performing a second EFO on the end of the bond wire at a second setting, after performing the first EFO, to fully form the FAB. The first EFO setting preferably is about 30 to 40% of the second EFO setting.

In another embodiment, the present invention provides a semiconductor device assembled using a particular process. The semiconductor device comprises an integrated circuit die having an active surface with die bonding pads, external electrical connection members, and a bond wire attached to one of the die bonding pads and attached to a contact area of one of the external electrical connection members by pre-forming a free air ball (FAB) on a tip of the bond wire with a first electric flame off (EFO) process, fully forming the FAB with a second EFO process, and then pressing the fully formed FAB against said contact area.

In yet another embodiment, the present invention provides a wire bonding apparatus for attaching bond wires to bonding pads on an active surface of a die and to electrical contact pads. The apparatus comprises a mechanical arm to which a capillary is attached at a distal end; a torch for generating a flame; a processor in communication with the mechanical arm for controlling movement of the arm, and in communication with the torch for controlling movement of the torch and generation of the flame; a display in communication with the processor for displaying bonding parameters, and for displaying a menu for entry of the bonding parameters; and an input device for entering the bonding parameters. The bonding parameters include settings for a first electronic flame off (EFO) process and a second EFO process so that when a bond wire is attached to an electrical contact pad, the first and second EFO processes are performed as part of the attachment process.

Referring now to FIGS. 2 to 4, a method of forming a free air ball (FAB) in accordance with an embodiment of the present invention is shown. FIG. 2 shows a wire 20 held by a capillary 22. As shown, an end 24 of the wire 30 extends out of an opening in the capillary 22. In one embodiment, the wire 20 extends a distance T_{L} of about 12 to 18 um out of the capillary 22. A wand or torch 26 is located proximate to the end 24 of the wire 20. The capillary 22 and the torch 26 are part of a wire bonding apparatus and are well known in the art, although specific settings will be discussed in detail below.

For forming a FAB having a diameter of around 28 um, the wire 20 has a diameter of 18 um. And in one embodiment, the capillary 22 has a face angle of 11 degree, a chamfer angle of 70 degree, a chamfer diameter of 31.75 um, an outer radius of 7.62 um, and a tip of 86.36 um. Such a capillary is commercially available from Kulicke & Soffa of Willow Grove, Pa.

In a wire bonding process, the wire 20 is threaded in the capillary 22 and then the capillary 22 is moved towards an electrical contact pad (not shown) to which the wire 20 is to be attached. Generally, when connecting bonding pads on a semiconductor die to electrical contacts of a substrate or contact areas of lead fingers of a lead frame, the wire 20 is first attached to the die bonding pad (called the first bond) and then to the corresponding contact area of the lead finger or substrate contact (called the second bond). Typically, the first bond is a ball bond and the second bond is a wedge bond. The present invention is particularly applicable to forming a FAB for the first bond.

Referring now to FIG. 3, in accordance with the present invention, once the end 24 of the wire 20 is located over the die bonding pad, a first electronic flame off (EFO) process is performed on the end 24 of the wire 20 at a first setting to pre-form a free air ball (FAB) 28 on the end 24 of the wire 20. The torch 26 preferably is a distance GL 750 um from the end 24 of the wire 20 when performing the first EFO and although the torch 26 is shown to be offset from the end 24 of the wire 20, in the presently preferred embodiment, the torch 26 is directly below the end 24 of the wire 20 (i.e., the wire 20 and an end of the torch 26 are aligned). In one embodiment, the first EFO process has an EFO fire time of 126 uS and an EFO current of 1860 mA.

Referring now to FIG. 4, after pre-forming the FAB 28, a second EFO process is performed on the end 24 of the bond wire 30 at a second setting, which causes a fully formed FAB 30 at the end 24 of the wire 20. In one embodiment, the second EFO is performed immediately after the first EFO and with settings of EFO fire time 420 uS and EFL current 6200 mA. Thus, in one embodiment, the first EFO setting is about 30 to 40% of the second EFO setting. Like with FIG. 3, although the EFO torch 26 is shown offset from the wire 20 and FAB 30, in a preferred embodiment, the EFO torch 26 is aligned with the wire 20 and directly beneath the end 24 of the wire 20. Also, the gap GL is 750 um, which is the same as the gap for the first EFO.

The fully formed FAB 40 is then pressed against the bonding surface (e.g., a die bonding pad) and attached thereto with an ultrasonic and/or thermosonic bonding process.

As is known by those of skill in the art, Copper tends to oxidize very quickly and thus copper wire usually is subjected to a forming gas, such as N2, during the wire bonding process. In one embodiment, the wire bonding process is performed using a forming gas with 95% N₂ and 5% H₂ during FAB formation.

The present invention is particularly suitable for copper bond wire having a diameter ranging from 18 to 50 microns in diameter. Although the present invention is particularly suited for forming first bonds, where the first bond is a ball bond, if a particular device requires the second bond also to be a ball bond, then the second bond can be performed using the two EFO steps described above. Thus, the two EFO process can be used to attach a wire to a bonding pad on an active face of a semiconductor die (the usual case), a contact area of a lead finger of a lead frame, or an electrical contact pad of a substrate.

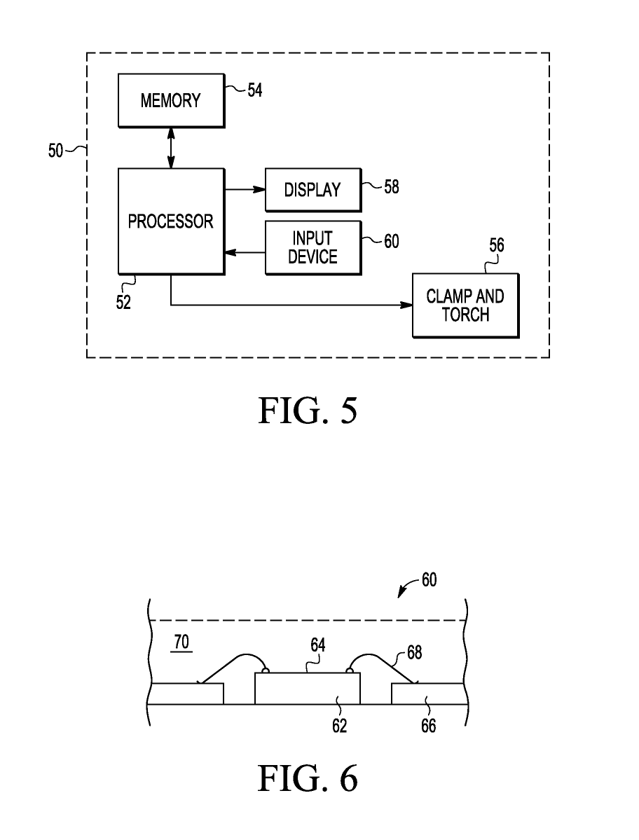

Referring now to FIG. 5, a schematic block diagram of a wire bonding apparatus 50 that can perform a wire bonding operation that includes the above-described dual EFO process is shown. The wire bonding apparatus 50 includes a processor 52, a memory 54, a clamp and torch assembly 56, a display device 58, and an input device 60. The clamp and torch assembly 56 includes a mechanical arm to which a capillary is attached at a distal end, and an electronic flame off torch maintained proximate to the capillary, for forming a FAB at the end of the wire. An end of a wire threaded through capillary can be bonded to a surface, such a bonding pad of a die, using the afore-described dual EFO wire bonding process.

The processor 52 is in communication with the mechanical arm for controlling movement of the arm, and in communication with the torch for controlling movement of the torch and generation of the flame. The display 58 is connected to and in communication with the processor 52 for displaying bonding parameters, and for displaying a menu for entry of the bonding parameters. The input device 60 also is connected to and in communication with the processor 52 for entering the bonding parameters. The memory 54 is used to store program code and the bonding parameters, as well as other data. According to the present invention, the bonding parameters include settings for a first electronic flame off (EFO) process and a second EFO process so that when a bond wire is attached to an electrical contact pad, the first and second EFO processes are performed as part of the attachment process. The input device 60 allows the parameters for the two EFO processes to be entered, such as EFO time, EFO current, distance between the end of the wire and the EFO torch, and time between the first and second EFO processes.

The wire bonding apparatus 50 can be implemented by modifying a commercially available wire bonding apparatus, such as the ASM Eagle 60, commercially available from ASM International of the Netherlands, by modifying the software of the apparatus.

Referring now to FIG. 6, an enlarged cross-sectional side view of a semiconductor device 60 in accordance with an embodiment of the present invention is shown. The device 60 includes an integrated circuit die 62 having an active surface 64 with die bonding pads located thereon. The bonding pads typically are located around the periphery of the die 62 but the bonding pads also could be formed in an array over a central area of the active surface 64. The device 60 also includes external electrical connection members 66, which in the embodiment shown, are lead fingers of a lead frame. A bond wire 68 is attached to one of the die bonding pads and attached to a contact area of one of the external electrical connection members 66 by pre-forming a free air ball (FAB) on a tip of the bond wire 68 with a first electric flame off (EFO) process, fully forming the FAB with a second EFO process, and then pressing the fully formed FAB against the contact area of the connection member 68. That is, the bond wire 68 is attached to the die bonding pad using the afore-described dual EFO process.

The bond wire 68 preferably is composed of copper and has a diameter of about 18 to 50 microns in diameter. A mold compound 70 at least partially covers the die 62, connection members 66, and the bond wire 68. At least a portion of the connection members 66 is exposed to allow for external electrical communication with the die 62.

Thus, while the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

1. A method of attaching a bond wire to an electrical contact pad, comprising:
holding the bond wire in a capillary, wherein an end of the wire extends out of an opening in the capillary;
moving the bond wire towards the electrical contact pad;
performing a first electric flame off (EFO) on the end of the bond wire at a first setting to pre-form a free air ball on the end of the wire; and
performing a second EFO on the end of the bond wire at a second setting, after performing the first EFO, to fully form the FAB.

2. The method of claim 1, wherein the bond wire is formed of Copper.

3. The method of claim 1, wherein the bond wire has a diameter of 18 to 50 microns in diameter and the FAB has a diameter of 1.4 to 1.6 times the wire diameter.

4. The method of claim 1, wherein a tail length of the wire before the first EFO is about 12 to 18 um and a gap between an EFO torch and an end of the tail is about 750 um mm when the first and second EFOs are performed.

5. The method of claim 4, wherein the second EFO setting is 6200 mA (EFO current) and the first EFO setting is about 30% of the first EFO setting.

6. The method of claim 5, wherein an EFO fire time for the first and second EFO settings is 126 uS and 420 uS.

7. The method of claim 6, wherein the second EFO is performed immediately after the first EFO.

8. The method of claim 1, wherein the electrical contact pad comprises one of an electrical contact pad of a substrate, a die pad on an active surface of an integrated circuit, and a lead finger of a lead frame.

9. The method of claim 8, further comprising the step of attaching the fully formed FAB to the electrical contact pad.

10. The method of claim 9, wherein the end of the bond wire is subjected to a forming gas during the first and second EFOs for preventing oxidation of the wire.

11. The method of claim 9, further comprising the step of attaching the fully formed FAB to the electrical contact pad using one of a thermosonic bonding process and an ultrasonic bonding process.

12. A semiconductor device, comprising:
an integrated circuit die having an active surface with die bonding pads;
external electrical connection members; and
a bond wire attached to one of the die bonding pads and attached to a contact area of one of the external electrical connection members by pre-forming a free air ball (FAB) on a tip of the bond wire with a first electric flame off (EFO) process, fully forming the FAB with a second EFO process, and then pressing the fully formed FAB against said contact area.

13. The semiconductor device of claim 12, wherein pre-forming the FAB is performed at a first EFO setting and fully forming the FAB is performed at a second EFO setting.

14. The semiconductor device of claim 13, wherein the first EFO setting is about 30 to 40% of the second EFO setting.

15. The semiconductor device of claim 12, wherein the bond wire is formed of Copper.

16. The semiconductor device of claim 12, further comprising a mold compound that covers at least the active surface of the integrated circuit and the bond wires.

17. A wire bonding apparatus for attaching bond wires to bonding pads on an active surface of a die and to electrical contact pads, the apparatus comprising:
a mechanical arm to which a capillary is attached at a distal end;
a torch for generating a flame;
a processor in communication with the mechanical arm for controlling movement of the arm, and in communication with the torch for controlling movement of the torch and generation of the flame;
a display in communication with the processor for displaying bonding parameters, and for displaying a menu for entry of the bonding parameters; and
an input device for entering the bonding parameters,
wherein the bonding parameters include settings for a first electronic flame off (EFO) process and a second EFO process so that when a bond wire is attached to an electrical contact pad, the first and second EFO processes are performed as part of the attachment process.
